(19) United States
(12) Patent Application Publication
(10) Pub. No.: US 2026/0301147 A1
(43) Pub. Date: Oct. 1, 2026

(54) PRODUCTION ASSISTANCE DEVICE AND PRODUCTION ASSISTANCE METHOD

(71) Applicant: FUJI CORPORATION, Chiryu (JP)

(72) Inventor: Tatsuji NOZAWA, Toyokawa-shi (JP)

(73) Assignee: FUJI CORPORATION, Chiryu (JP)

(21) Appl. No.: 19/477,209

(22) PCT Filed: May 10, 2023
(86) PCT No.: PCT/JP2023/017591

§ 371 Date: Oct. 21, 2025

(51) Int. Cl. G06T 7/00; G06T 7/73; G06V 10/70; G06V 10/98

(52) U.S. Cl. CPC G06T 7/0004; G06T 7/73; G06V 10/70; G06V 10/993; G06T 2207/30141; G06T 2207/30168

(57) ABSTRACT

A production assistance device includes a generation section configured to generate recognition data used for a recognition process for a component during a mounting process by a component mounter, based on board data indicating a feature portion of a predetermined region including a mounting target position of the component on a board.

### TECHNICAL FIELD

The present disclosure relates to a production assistance device and a production assistance method.

### BACKGROUND ART

A production assistance device is applied to a component mounter that mounts a component on a board. In a mounting process, the component mounter executes, for example, a recognition process for the picked-up component. In this recognition process, for example, image data acquired by imaging a target component is subjected to image processing, and it is recognized whether the target component is suitable by collating the image data with recognition data. Patent Literature 1 discloses a configuration in which a template as recognition data used for a recognition process is generated based on data on an electrode of a component.

### CITATION LIST

### Patent Literature

Patent Literature 1: WO 2020/012621

### BRIEF SUMMARY

### Technical Problem

It is desirable that the recognition data as described above is generated more appropriately so that the recognition process for the component is executed with high accuracy. An object of the present description is to provide a production assistance device and a production assistance method for generating recognition data with a configuration different from the configuration of Patent Literature 1.

### Solution to Problem

The present description discloses a production assistance device including: a generation section configured to generate recognition data used for a recognition process for a component during a mounting process by a component mounter, based on board data indicating a feature portion of a predetermined region including a mounting target position of the component on a board.

The present description further discloses a production assistance method including: a generation step of generating recognition data used for a recognition process for a component during a mounting process by a component mounter, based on board data indicating a feature portion of a predetermined region including a mounting target position of the component on a board.

### ADVANTAGEOUS EFFECTS

With such a configuration, since the recognition data based on the board data indicating the feature portion of the predetermined region including the mounting target position of the component on the board is generated, for example, the recognition process for the component can be executed depending on whether the component that is a recognition target corresponds to the feature portion of the board. Accordingly, it is possible to generate necessary recognition data without requiring design data of the component, and, as a result, it is possible to improve production efficiency.

### BRIEF DESCRIPTION OF DRAWINGS

FIG. 1 is a schematic diagram illustrating a production system to which a production assistance device is applied.

FIG. 2 is a plan view schematically illustrating a component mounter.

FIG. 3 is a side partial cross-sectional view illustrating a configuration of a part camera.

FIG. 4 is a flowchart illustrating a mounting process by the component mounter.

FIG. 5 is a block diagram illustrating the production system.

FIG. 6 is a diagram illustrating a first form of recognition data generated based on board data.

FIG. 7 is a diagram illustrating a second form of the recognition data generated based on the board data.

FIG. 8 is a flowchart illustrating a recognition data generation process and an imaging condition setting process.

FIG. 9 is a diagram illustrating an electrode recognition process in the recognition data generation process.

FIG. 10 is a table illustrating a relationship between recognition results and evaluation values for multiple types of imaging conditions.

### DESCRIPTION OF EMBODIMENTS

### 1. Overview of Production Assistance Device

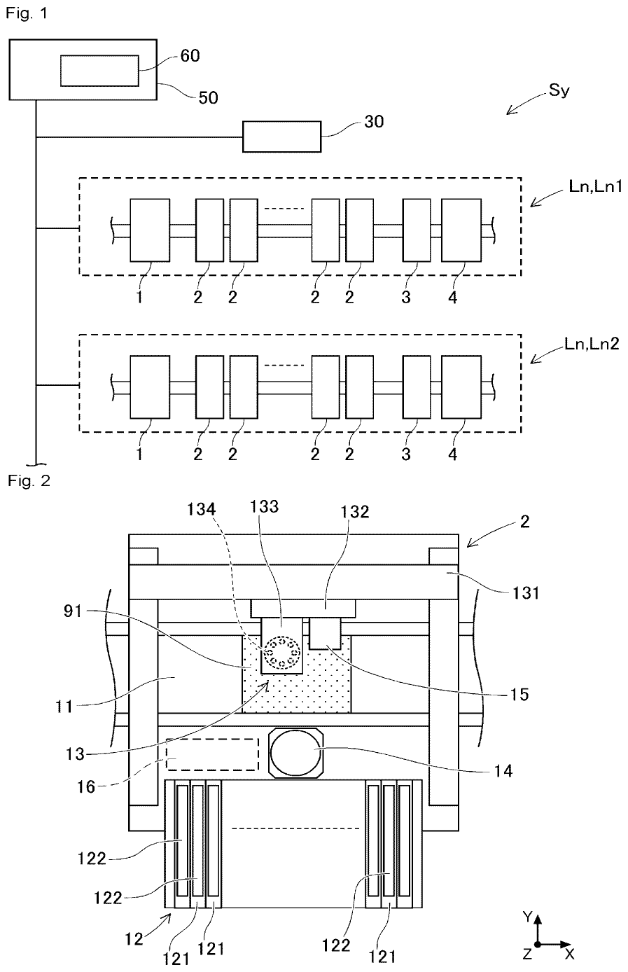

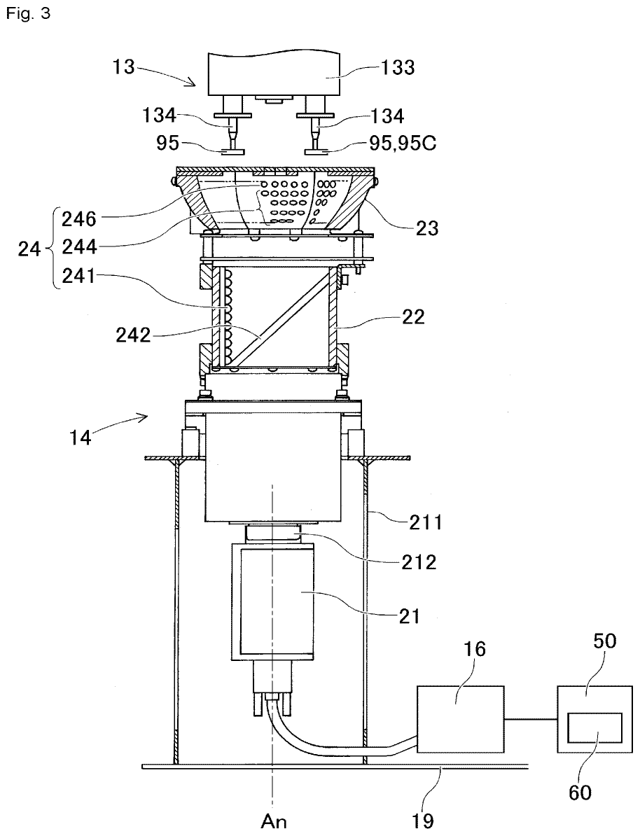

Production assistance device 60 assists the production of a product board by generating recognition data used for a recognition process for a component during a mounting process by component mounter 2. Component mounter 2 performs the mounting process of mounting the component on board 91 as predetermined board work. As illustrated in FIG. 1, production line Ln is formed such that multiple board work machines are installed in a conveyance direction of the board. Each of the multiple board work machines is communicably connected with host computer 50 that collectively controls production line Ln. Production line Ln includes printer 1, multiple component mounters 2, reflow oven 3, and inspector 4 as the multiple board work machines.

Printer 1 prints paste-like solder at a mounting position of the component on the conveyed-in board. Each of multiple component mounters 2 mounts the component on the board conveyed from an upstream side in production line Ln. A configuration of component mounter 2 will be described later. Reflow oven 3 heats the board conveyed from the upstream side in production line Ln, melts the solder on the board, and performs soldering. Inspector 4 inspects whether an appearance or a function of a board product produced by production line Ln is normal.

Multiple production lines Ln (Ln1, Ln2, . . .) may be formed in production system Sy that produces the board product. A configuration of each of multiple production lines Ln can be added or changed as appropriate in accordance with, for example, a type of the board product to be produced. Specifically, the board work machines such as a buffer device that temporarily holds the conveyed board, a board supply device, or a board flipping device, various types of inspection devices, a shield mounting device, an adhesive application device, an ultraviolet ray irradiation device, and the like can be installed in multiple production lines Ln as appropriate.

Setup device 30 is used for the setup of the device used for the mounting process scheduled to be executed, the generation or the correction of various data, and the like. Setup device 30 is used, for example, for an operation of loading the component into a feeder, an operation of removing the component from a feeder used for the mounting process, and the like. Setup device 30 is communicably connected to host computer 50, and receives and outputs various information related to the setup.

### 2. Configuration of Component Mounter 2

Component mounter 2 includes, as illustrated in FIG. 2, board conveyance device 11, component supply device 12, component transfer device 13, part camera 14, board camera 15, and control device 16. In the following description, a front-rear direction (up-down direction in FIG. 2) of component mounter 2 which is a horizontal direction is defined as a Y direction, a left-right direction (left-right direction in FIG. 2) of component mounter 2 which is a horizontal direction intersecting the Y direction is defined as an X direction, and a vertical direction (front-rear direction in FIG. 2) orthogonal to the X direction and the Y direction is defined as a Z direction.

### 2-1. Board Conveyance Device

Board conveyance device 11 subsequently conveys boards 91 in the conveyance direction and positions board 91 at a predetermined position in component mounter 2.

### 2-2. Component Supply Device 12

Component supply device 12 supplies the component to be mounted on board 91. Component supply device 12 is equipped with feeders 122 in multiple slots 121 arranged side by side in the X direction. Feeder 122 employs a tape feeder that advances a carrier tape that houses numerous components, thereby supplying the components for pickup. Component supply device 12 may supply, for example, relatively large components in a state in which the components are arranged on a tray placed on a pallet. In the above configuration, component supply device 12 supplies the components by pulling out predetermined pallets from a housing device that houses multiple pallets in accordance with the mounting process.

### 2-3. Component Transfer Device 13

Component transfer device 13 transfers the component supplied by component supply device 12 to a predetermined mounting position on board 91 conveyed into component mounter 2 by board conveyance device 11. Head drive device 131 of component transfer device 13 moves moving body 132 in the horizontal direction (X direction and Y direction) with a linear motion mechanism. Mounting head 133 is fixed to moving body 132 in an exchangeable manner by a clamp member (not illustrated). Various tools are detachably attached to mounting head 133.

The tool includes suction nozzle 134 as a holding member that holds the component. Suction nozzle 134 picks up and holds the component by using supplied negative pressure air. A lifting and lowering position or angle of suction nozzle 134 with respect to mounting head 133 and a supply state of the negative pressure air are controlled. Further, a chuck or the like that holds the component by gripping the component may be adopted as the holding member. In addition, mounting head 133 includes, as other tools, for example, a pin used for an operation of applying a bonding material to the board, a picker used for pickup of a backup device of a backup device (not illustrated), and the like.

### 2-4. Part Camera 14 and Board Camera 15

Part camera 14 and board camera 15 are digital imaging devices including an imaging element, such as a CMOS. Part camera 14 and board camera 15 perform imaging based on a control signal and send image data acquired by the imaging. Part camera 14 is configured to image the component held by suction nozzle 134 from below. Details of part camera 14 will be described later.

Board camera 15 is provided integrally with mounting head 133 on moving body 132 to be movable in the horizontal direction. Board camera 15 is configured to image board 91 from above. In addition, board camera 15 can use various devices or the like as an imaging target as long as the various devices are within an operation range of moving body 132 in addition to using a surface of board 91 as the imaging target. For example, board camera 15 is used for imaging a predetermined portion of board 91 before the component is mounted. As described above, board camera 15 can be used commonly to image different imaging targets to acquire image data used for various types of image processing.

### 2-5. Control Device 16

Control device 16 mainly includes CPU, various memories, and a control circuit. Control device 16 executes the mounting process of mounting the component on board 91. In the mounting process, control device 16 controls the operation of component transfer device 13 based on information output from various sensors, results of the image processing, a control program stored in advance, or the like. As a result, the positions and the angles of multiple suction nozzles 134 supported by mounting head 133 are controlled. The control program indicates the mounting position, the mounting angle, and the component type of the component mounted on board 91 in the mounting process in a scheduled mounting order.

Control device 16 stores recognition data Dc downloaded from host computer 50. Here, “recognition data Dc” is a template used for the recognition process for the component during the mounting process as described above. In the recognition process, for example, control device 16 performs image processing on the image data acquired by imaging the target component, and recognizes whether the target component is suitable by collating the image data with recognition data Dc. In addition, control device 16 may use the imaging conditions in the imaging of the target component by downloading the imaging conditions from host computer 50. Details of the mounting process by control device 16 will be described later.

### 3. Detailed Configuration of Part Camera 14

Part camera 14 includes camera main body 21, coupling section 22, upper bowl section 23, and illumination section 24. Camera main body 21 is mounted on base 19 via support table 211 so that optical axis An is aligned with the Z direction. Optical axis An of camera main body 21 is a light incident axis perpendicular to the imaging element. Light incident section 212 on which light from above is incident is formed at the center of an upper portion of camera main body 21. Coupling section 22 is provided above camera main body 21. Coupling section 22 is a tubular member having a rectangular cross section. Upper bowl section 23 is provided at an upper end portion of coupling section 22. Upper bowl section 23 is formed as a bottomless and upwardly open bowl.

Illumination section 24 is disposed from an inner surface of coupling section 22 to an inner surface of upper bowl section 23. Specifically, illumination section 24 is provided on one side surface of an inner wall of coupling section 22, and includes epi-illumination light source 241 including numerous LEDs. Illumination section 24 includes half mirror 242 provided to obliquely cross the inside of coupling section 22. Half mirror 242 reflects horizontal epi-illumination light emitted from epi-illumination light source 241 upward in the Z direction, and transmits light from above toward light incident section 212 of camera main body 21. Epi-illumination light source 241 is a light source that emits light parallel to optical axis An toward the imaging target.

Illumination section 24 includes oblique illumination light source 244 that is provided on a bowl-shaped inner surface of upper bowl section 23 and that includes numerous LEDs. Oblique illumination light source 244 is configured such that, for example, multiple LED arrays arranged at equal intervals in the horizontal direction and around optical axis An are arranged in four stages in the up-down direction. Oblique illumination light source 244 is a light source that emits light inclined relative to optical axis An toward the imaging target. Furthermore, illumination section 24 includes side illumination light source 246 that is provided on an upper edge portion of the bowl-shaped inner surface of upper bowl section 23 and includes numerous LEDs. Side illumination light source 246 is a light source that emits light orthogonal to optical axis An from the side toward the imaging target.

Part camera 14 executes an imaging process in accordance with predetermined imaging conditions in response to the control signal from control device 16. The imaging process includes control of an imaging operation of camera main body 21 and an illumination operation of illumination section 24. In addition, the imaging conditions may include ON/OFF switching of each light source, irradiation time, light amount, and the like. Illumination section 24 irradiates the imaging target with illumination light in accordance with the imaging conditions. Further, the imaging conditions may include an exposure timing by the imaging element, an exposure time (shutter speed), and the like. Part camera 14 images the imaging target and sends the image data acquired by the imaging to control device 16.

For part camera 14, multiple patterns of imaging conditions may be set in advance and selected by the control signal, or at least a part of the imaging conditions may be set by the control signal. For example, part camera 14 downloads multiple imaging conditions set in advance in accordance with the type of the component that is the imaging target from host computer 50, and stores the multiple imaging conditions. Then, the imaging conditions are designated by the control signal in accordance with the type of the component that is the imaging target, and part camera 14 executes the imaging process under the imaging conditions (the type of the light source, the irradiation time, the exposure time, and the like).

The above-described imaging conditions can be switched depending on an imaging type in addition to the type of the component. The imaging type includes on-the-fly imaging, in which imaging is performed while maintaining the horizontal movement of mounting head 133 that holds the component that is the imaging target during the imaging process, and stop-imaging in which imaging is performed after temporarily stopping mounting head 133 above part camera 14.

### 4. Mounting Process by Component Mounter 2

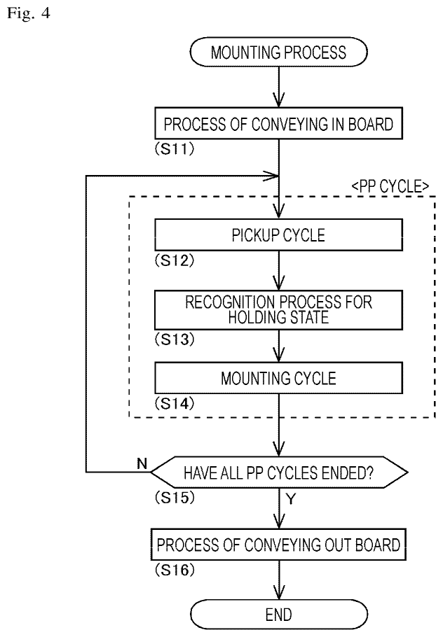

The mounting process by component mounter 2 will be described with reference to FIG. 4. In the mounting process, first, as illustrated in FIG. 4, board conveyance device 11 of component mounter 2 performs a process of conveying in board 91 (S11). Accordingly, board 91 is conveyed into component mounter 2 and positioned at a predetermined position in component mounter 2.

Next, control device 16 executes a pick-and-place cycle (PP cycle). In the PP cycle, control device 16 executes a pickup cycle in which a pickup operation of picking up the component is repeated by using multiple suction nozzles 134 (S12). In this case, control device 16 controls the operation of component transfer device 13 so that mounting head 133 is positioned in accordance with the position to which the component that is the pickup target is supplied.

Subsequently, control device 16 executes a recognition process for a holding state of the component held by each of multiple suction nozzles 134 (S13). Specifically, control device 16 moves mounting head 133 above part camera 14 and sends the control signal as an imaging command to part camera 14. Control device 16 recognizes a posture (position and angle) of the component held by each of multiple suction nozzles 134 by performing the image processing on the image data acquired by the imaging with part camera 14. The result of the recognition process for the holding state (S13) includes an operation result indicating whether the pickup operation is normally performed, together with the recognized posture of the component.

In the recognition process for the holding state (S13), recognition data Dc whether the picked-up component is suitable is used. Various forms can be adopted as recognition data Dc. For example, recognition data Dc is also referred to as shape data when indicating information on the shape of the component, and may include information such as an outer dimension of the component, an allowable error of the dimension, and a position and an appearance color of a lead in a case of a lead component. Recognition data Dc may be data indicating whether the positions and the number of bumps on a mounting surface (lower surface) of the component are suitable.

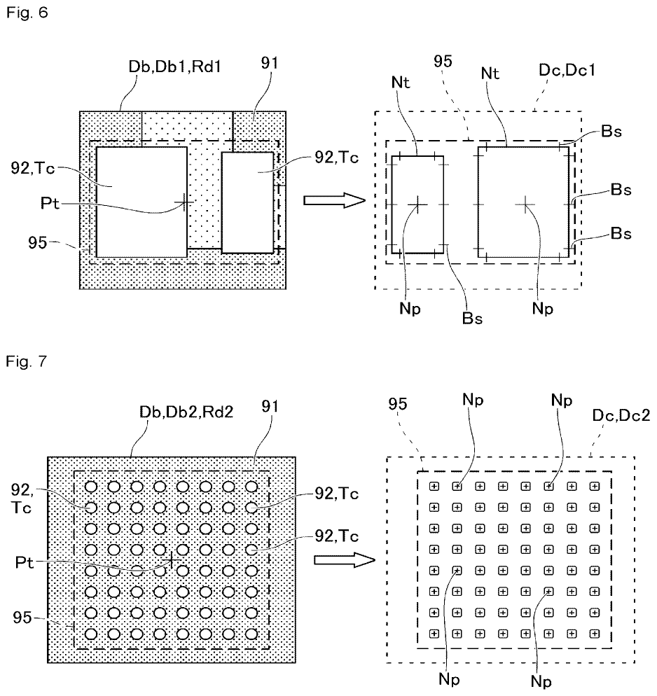

Specifically, as illustrated on the right side of FIG. 6, recognition data Del may have outer contour line Nt indicating a shape of an electrode portion of the component or seek line Bs intersecting outer contour line Nt. Control device 16 recognizes the holding state of the picked-up component by performing the image processing on the image data acquired by the imaging with part camera 14, searching for an electrode indicated by outer contour line Nt or an electrode intersecting seek line Bs in the image data, and calculating the position and angle of the component relative to a reference position of mounting head 133 when the electrode is present.

As illustrated on the right side of FIG. 7, recognition data Dc2 has position information indicating center position Np corresponding to each of multiple bumps arranged on the mounting surface (lower surface) of the component. Recognition data Dc2 indicates the positions and the number of the multiple bumps in the component suitable for the mounting process by the positions and the number of multiple center positions Np. Control device 16 recognizes the holding state of the picked-up component by performing the image processing on the image data acquired by the imaging with part camera 14, searching for the bump indicated at center position Np in the image data, and calculating the position and angle of the component relative to a reference position of mounting head 133 when the position and the number are suitable.

In the recognition process using seek line Bs and center position Np in recognition data Dc as described above, since the outer shape of the electrode or the bump of the component is not collated, the information on these shapes can be omitted in recognition data Dc. This is because it is sufficient that each electrode of the component mounted on board 91 is electrically connected to wiring portion 92 (see the left side of FIG. 6 and the left side of FIG. 7) such as a land or a pad of board 91.

Here, control device 16 may execute image processing on image data acquired by imaging the component, for example, with a head camera unit provided integrally with mounting head 133 from side, below, or above, in addition to part camera 14. In such image processing, the recognition data corresponding to the imaging direction is used.

Thereafter, control device 16 executes a mounting cycle in which a mounting operation of mounting the component is repeated using multiple suction nozzles 134 (S14). In the mounting operation of the mounting cycle (S14), control device 16 controls the operation of mounting head 133 so that each of components is mounted at the mounting position designated by the control program. Further, control device 16 controls the operation of mounting head 133 so that suction nozzle 134 is positioned and oriented relative to the mounting position based on the result of the recognition process (S13).

Control device 16 determines whether all the PP cycles have ended based on the control program (S15). When all the PP cycles have not ended (S15:No), the PP cycle (S12 to S14) is executed. When all the PP cycles have ended (S15:Yes), control device 16 executes a process of conveying out board 91 (S16). In the process of conveying out board 91, board conveyance device 11 unclamps positioned board 91 and conveys board 91 out of component mounter 2.

### 5. Configuration of Production Assistance Device 60

Recognition data Dc used in the recognition process for the component (S13) is generated based on, for example, design information of the target component, and is generated by performing the image processing on the image data acquired by imaging the target component. Here, for the determination of whether the component recognized in the recognition process (S13) is suitable for the mounting process, in addition to the method based on the type of the component, as described in the processing using recognition data Dc1 of FIG. 6 and recognition data Dc2 of FIG. 7, a method based on whether the component corresponds to the shape of wiring portion 92 on board 91 side on which the component is mounted can be adopted.

In the present embodiment, production assistance device 60 automatically generates recognition data Dc applied to the latter determination method. Production assistance device 60 generates recognition data De based on board data Db on board 91. Accordingly, recognition data Dc used in the mounting process can be generated in advance regardless of the supplied component. Further, production assistance device 60 has a configuration of setting the imaging conditions applied when part camera 14 images the component in the recognition process (S13). As a result, production assistance device 60 improves the accuracy of the recognition process (S13) and assists the production of the product board.

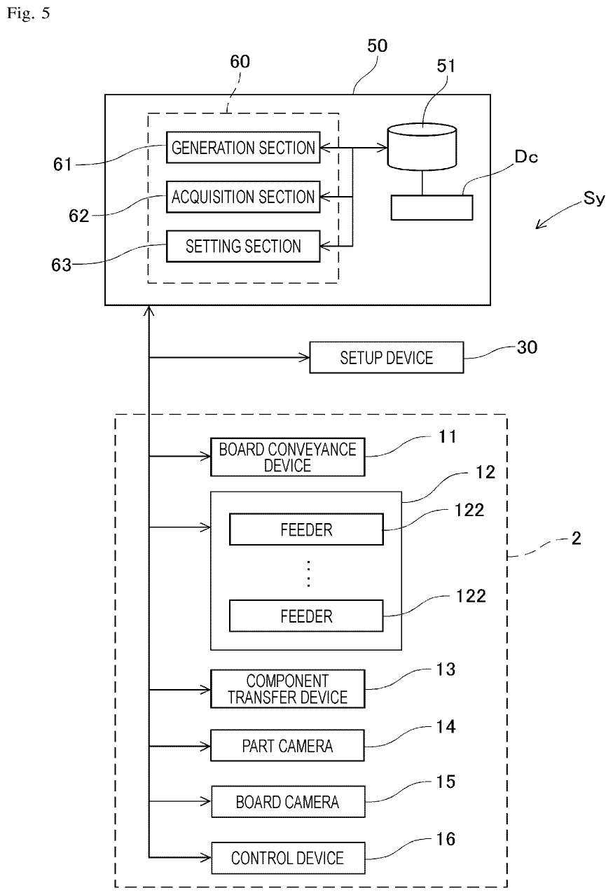

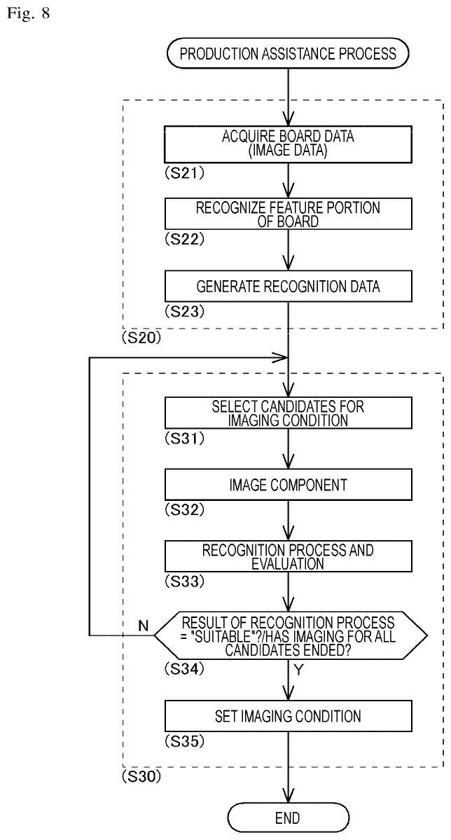

As illustrated in FIG. 5, production assistance device 60 includes generation section 61, acquisition section 62, and setting section 63. Production assistance device 60 executes a production assistance process illustrated in FIG. 8. In the production assistance process, generation section 61 and acquisition section 62 execute a generation process for recognition data Dc (generation step, S20). In the production assistance process, setting section 63 executes a setting process for the imaging conditions (setting step, S30).

### 5-1. Generation Section 61 and Acquisition Section 62

Generation section 61 generates recognition data Dc based on board data Db indicating feature portion Tc of predetermined region Rd including mounting target position Pt of component 95 on board 91. Here, board data Db may be design data of board 91 or may be data acquired by acquisition section 62.

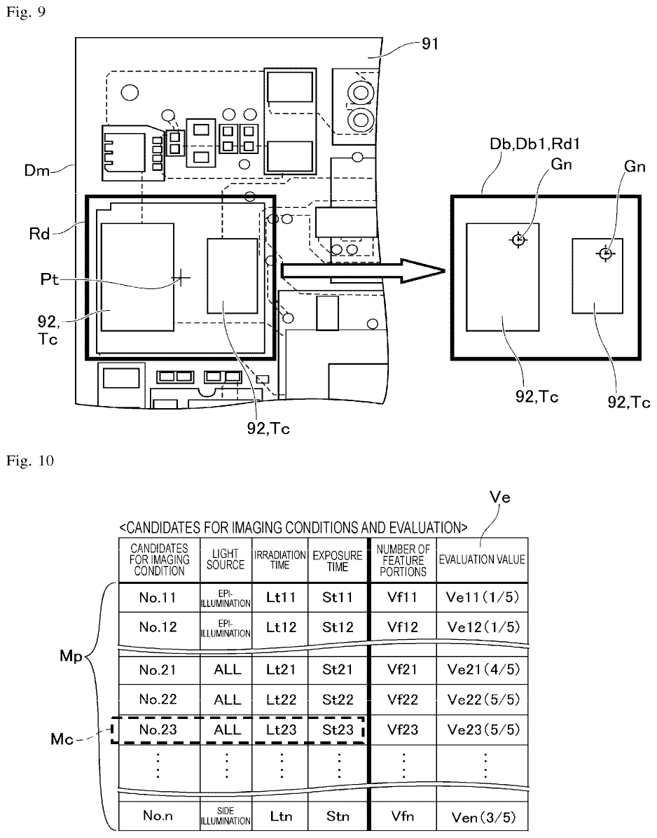

Acquisition section 62 first acquires board data Db (S21) in the generation process for recognition data Dc (S20). Specifically, as illustrated in FIG. 9, acquisition section 62 performs the image processing on the image data acquired by imaging predetermined region Rd (indicated by a thick solid line in FIG. 9) to acquire board data Db indicating the position of feature portion Tc. Here, predetermined region Rd includes mounting target position Pt at which a predetermined type of component 95 is mounted in the mounting process.

In predetermined region Rd, there is feature portion Tc serving as a reference of the mounting operation of component 95. In the present embodiment, feature portion Tc is a portion electrically connected to the electrode portion of component 95, and is wiring portion 92 forming a pattern such as a land or a pad formed on board 91. Feature portion Tc may include a fiducial mark attached to board 91, a fiducial line indicating a shape of at least a part of component 95 to be mounted, and the like.

The image data is acquired by imaging board 91 used for the mounting process by predetermined imaging equipment. The imaging equipment may be an external device installed around host computer 50 or may be equipment provided in setup device 30. Further, the image data may be acquired by imaging predetermined region Rd with board camera 15 provided in component mounter 2 and capable of imaging board 91.

Next, acquisition section 62 recognizes feature portion Tc of board data Db (S22). In the recognition process, acquisition section 62 may perform binarization processing using, for example, a predetermined threshold value as the image processing, and extract feature portion Tc having brightness different from that of a board main body in predetermined region Rd. In addition, acquisition section 62 may display predetermined region Rd on a monitor (not illustrated) and receive the designation of the region included in feature portion Tc by an operator. Specifically, as illustrated on the right side of FIG. 9, when the operator designates designation point Gn, regions having the same brightness (for example, two wiring portions 92) are designated as a closed figure.

Generation section 61 generates recognition data Dc based on board data Db acquired by acquisition section 62 (S23). Specifically, in the generation process, as illustrated in FIG. 6, generation section 61 inverts multiple feature portions Tc in board data Db symmetrically with respect to a predetermined axis (in the present embodiment, as illustrated on the right side of FIG. 6, the left and right are inverted). This is because, in the recognition process for component 95 using recognition data Dc, the image data obtained by imaging component 95 from below is used, and thus the appearance of component 95 matches the appearance of the lower surface of component 95. When the image data acquired in the recognition process is inverted, the inversion process for multiple feature portions Tc in board data Db is omitted in the generation process (S23).

In the generation process (S23), generation section 61 determines that the electrode portion corresponding to feature portion Tc is present in component 95, and sets outer contour line Nt indicating the shape of the electrode portion or seek line Bs intersecting outer contour line Nt in accordance with predetermined generation parameters. As the generation parameters, for example, the type of recognition data Dc (outer contour line Nt, seek line Bs, center position Np, a combination thereof, and the like), an interval of seek lines Bs, an allowable error, and the like are set in advance for each type of component 95.

By executing the generation process (S23), generation section 61 generates recognition data Dc1 and Dc2 corresponding to the recognition process for component 95 based on board data Db1 and Db2 as illustrated in FIGS. 6 and 7. Recognition data Dc2 illustrated in FIG. 7 indicates the positions and the number of the multiple electrode portions corresponding to multiple feature portions Tc in predetermined region Rd2. Generated recognition data Dc is stored in storage section 51 of host computer 50.

### 5-2. Setting Section 63

The mounting process includes a process of recognizing component 95 by applying recognition data Dc to the image data acquired by imaging component 95 (S13). The image data is acquired, for example, by imaging component 95 from below with part camera 14. Part camera 14 executes the imaging process in accordance with the predetermined imaging conditions.

In this case, depending on the imaging conditions, for example, the outer shape or the electrode portion on the lower surface of component 95 may become unclear, or multiple electrode portions may be recognized as one electrode portion. In this case, even when recognition data Dc is used, there is a risk of failing to accurately recognize whether component 95 is suitable for the mounting process or in what posture component 95 is held when component 95 is suitable.

Therefore, setting section 63 of production assistance device 60 sets the imaging conditions when the image data used for the recognition process for component 95 is acquired, based on recognition data Dc (S30). Setting section 63 first selects candidates for the imaging conditions (S31). As illustrated in FIG. 10, the type of the light source, the irradiation time, the exposure time, and the like are set for each candidate for the imaging conditions. Setting section 63 may select one from among all the candidates, or may select one from among predetermined types of light sources in accordance with past results of the recognition process and the type of component 95. Hereinafter, the “candidates for the imaging conditions” are also referred to as “preliminary imaging conditions Mp”. As described above, setting section 63 executes the condition setting step (S31) of setting preliminary imaging conditions Mp when the preliminary image data is acquired.

Next, setting section 63 acquires the preliminary image data by imaging component 95 (acquisition step, S32). In order to distinguish from the “image data” acquired by imaging board 91, the “image data” in the setting process of the imaging process is referred to as “preliminary image data”. Here, components 95 show individual differences, and the appearance in the image data may fluctuate even under the same imaging conditions. Therefore, when the preliminary image data is acquired, it is preferable to set in advance, as the imaging target, suitable component 95C that is component 95 scheduled to be used for the mounting process having a standard shape and color and is suitable for the mounting process.

Setting section 63 executes the acquisition step (S32), and acquires the preliminary image data by imaging suitable component 95C. Setting section 63 may perform the acquisition step (S32) by the imaging with the same imaging equipment as part camera 14 of component mounter 2. In the present embodiment, setting section 63 acquires the preliminary image data by imaging suitable component 95C with part camera 14 in a state where suitable component 95C is held by mounting head 133 of component mounter 2. Thus, an image can be captured in the same imaging environment as in the mounting process.

Subsequently, setting section 63 executes the recognition process in which recognition data Dc is applied to the preliminary image data, and determines whether the preliminary image data is suitable (determination step, S33). Setting section 63 performs, for example, the binarization processing on the preliminary image data as the image processing as in the recognition process, and further determines whether component 95 is suitable using recognition data Dc. Here, since component 95 included in the preliminary image data is suitable component 95C suitable for the mounting process, setting section 63 recognizes that there is a defect in the preliminary imaging conditions when it is determined that component 95 is not suitable in the determination step.

Meanwhile, when it is determined in the determination step that suitable component 95C is suitable, setting section 63 recognizes that the preliminary imaging conditions are good. Setting section 63 calculates evaluation value Ve indicating a degree of appropriateness of the preliminary image data in the determination step. As illustrated in FIG. 10, for example, five-stage evaluation (1 to 5/5) may be used. Setting section 63 may calculate evaluation value Ve based on the number (Vf11, Vf12, . . .) of feature portions (electrode portions or the like) of component 95 recognized in the determination step, the allowable error set in recognition data Dc, or a degree of displacement from an ideal shape.

When the result of the recognition process to which recognition data Dc is applied indicates “suitable” in the determination step (S34:Yes), that is, when the positions and the number of multiple feature portions Tc in suitable component 95C can be appropriately recognized, setting section 63 sets the candidates for the imaging conditions (preliminary imaging conditions) selected in S31, as the imaging conditions (S35). On the other hand, when the result of the recognition process to which recognition data Dc is applied indicates “not suitable” in the determination step (S34:No), setting section 63 determines that the candidates for the imaging conditions selected in S31 are not suitable for the mounting process, and repeatedly executes the setting cycle including S31 to S33.

In addition, even when the result of the recognition process in the determination step indicates “suitable” as described above, setting section 63 may repeatedly execute the setting cycle (S31 to S33) until the imaging ends for all the candidates set in advance in order to search for more suitable imaging conditions (S34). As a result, the positions and the number of multiple feature portions Tc in suitable component 95C are acquired for each of all preliminary imaging conditions Mp, and evaluation value Ve is calculated.

Then, when feature portion Tc of suitable component 95C can be appropriately recognized in multiple iterations of the determination step, setting section 63 sets preliminary imaging conditions Mp as condition candidates for imaging conditions Mc, and sets one selected from among the multiple condition candidates based on evaluation value Ve as imaging conditions Mc (S35). Accordingly, even when it is determined that multiple preliminary imaging conditions Mp are suitable, a condition candidate having higher evaluation value Ve can be set as imaging conditions Mc.

### 6. Effects of Configuration of Embodiment

With the configuration of production assistance device 60 and the production assistance method (corresponding to the production assistance process of FIG. 8) as described above, recognition data Dc based on board data Db indicating feature portion Tc of predetermined region Rd including mounting target position Pt of component 95 on board 91 is generated. Accordingly, control device 16 of component mounter 2 can execute the recognition process for component 95 depending on whether component 95 that is the recognition target corresponds to feature portion Tc of board 91. Accordingly, it is possible to generate necessary recognition data Dc without requiring design data of component 95, and, as a result, it is possible to improve production efficiency.

In addition, it is possible to set imaging conditions Mc for executing a suitable recognition process for component 95 using generated recognition data Dc. As a result, imaging for acquiring the image data used for the recognition process can be suitably performed, and the occurrence of a mistake in the recognition process can be prevented. As described above, production assistance device 60 and the production assistance method can improve the accuracy of the recognition process (S13) and assist the production of the product board as a result.

### 7. Modification of Embodiment

In the embodiment, production assistance device 60 includes setting section 63 that sets imaging conditions Mc. Alternatively, production assistance device 60 may have a configuration in which, for example, the operator sets imaging conditions Mc as in the conventional art, and setting section 63 is omitted. Similarly, in the production assistance method, the setting step (S30) for imaging conditions Mc can be omitted.

In the embodiment, production assistance device 60 is incorporated into host computer 50. Alternatively, production assistance device 60 may be incorporated into component mounter 2 or setup device 30. For example, in a configuration in which production assistance device 60 is incorporated into control device 16 of component mounter 2, board camera 15 images board 91 first conveyed into component mounter 2 before production, and the generation step (S20) for recognition data Dc is executed.

Further, component 95 scheduled to be mounted is picked up and imaged by part camera 14 under multiple preliminary imaging conditions Mp, and the setting step (S30) for the imaging conditions is executed. This makes it possible to generate recognition data Dc before execution of the mounting process, and set the imaging conditions suitable for recognition data Dc. In this configuration as well, the same effects as in the embodiment are obtained.

### REFERENCE SIGNS LIST

2: component mounter, 11: board conveyance device, 12: component supply device, 13: component transfer device, 131: head drive device, 132: moving body, 133: mounting head, 134: suction nozzle, 14: part camera, 15: board camera, 16: control device, 21: camera main body, 24: illumination section, 241: epi-illumination light source, 242: half mirror, 244: oblique illumination light source, 246: side illumination light source, 30: setup device, 50: host computer, 51: storage section, 60: production assistance device, 61: generation section, 62: acquisition section, 63: setting section, 91: board, 92: wiring portion, 95: component, 95C: suitable component, Bs: seek line, Nt: outer contour line, Np: center position, Dc: recognition data, Db: board data, Dm: image data, Mc: imaging conditions, Mp: preliminary imaging conditions, Pt: mounting target position, Rd: predetermined region, Tc: feature portion, Ve: evaluation value, Sy: production system, Ln: production line

1. A production assistance device comprising:
a generation section configured to generate recognition data used for a recognition process for a component during a mounting process by a component mounter, based on board data indicating a feature portion of a predetermined region including a mounting target position of the component on a board.

2. The production assistance device according to claim 1, further comprising:
an acquisition section configured to acquire the board data indicating a position of the feature portion by performing image processing on image data acquired by imaging the predetermined region.

3. The production assistance device according to claim 2,
wherein the acquisition section is configured to acquire the board data by performing the image processing on the image data acquired by imaging the predetermined region with a board camera provided in the component mounter and capable of imaging the board.

4. The production assistance device according to claim 1,
wherein the feature portion is a portion electrically connected to an electrode portion of the component, and
the recognition data indicates positions and the number of multiple electrode portions corresponding to multiple feature portions in the predetermined region.

5. The production assistance device according to claim 1,
wherein the recognition process includes a process of recognizing the component by applying the recognition data to image data acquired by imaging the component, and
the production assistance device further comprises a setting section configured to set imaging conditions when the image data used for the recognition process is acquired based on the recognition data.

6. The production assistance device according to claim 5,
wherein the setting section is configured to repeatedly execute a setting cycle including an acquisition step of acquiring preliminary image data by imaging a suitable component that is the component scheduled to be used for the mounting process and is suitable for the mounting process, a determination step of determining whether the preliminary image data is appropriate by executing the recognition process in which the recognition data is applied to the preliminary image data, and a condition setting step of setting preliminary imaging conditions when the preliminary image data is acquired, and set the imaging conditions based on a result of the determination step and the preliminary imaging conditions.

7. The production assistance device according to claim 6,
wherein the setting section is configured to, when positions and the number of multiple feature portions in the suitable component are appropriately recognizable in the determination step, set the preliminary imaging conditions when the preliminary image data is acquired, as the imaging conditions.

8. The production assistance device according to claim 7,
wherein the setting section is configured to, in the determination step, calculate an evaluation value indicating a degree of appropriateness of the preliminary image data, and the setting section is configured to, when the positions and the number of the multiple feature portions in the suitable component are appropriately recognizable in multiple iterations of the determination step, set multiple preliminary imaging conditions when the preliminary image data is acquired, as condition candidates for the imaging conditions, and set one selected from among multiple condition candidates based on the evaluation value, as the imaging conditions.

9. The production assistance device according to claim 6,
wherein the setting section is configured to, in the acquisition step, acquire the preliminary image data by imaging the suitable component with a part camera provided in the component mounter and capable of imaging the component.

10. The production assistance device according to claim 5,
wherein the imaging conditions include a type and an exposure time of a light source that emits light when the component is imaged.

11. A production assistance method comprising:
a generation step of generating recognition data used for a recognition process for a component during a mounting process by a component mounter, based on board data indicating a feature portion of a predetermined region including a mounting target position of the component on a board.
